(19) United States
(12) Patent Application Publication
(10) Pub. No.: US 2025/0183242 A1
(43) Pub. Date: Jun. 5, 2025

(54) SEMICONDUCTOR PACKAGE

(71) Applicant: Samsung Electronics Co., Ltd., Suwon-si (KR)

(72) Inventors: Seokgeun Ahn, Suwon-si (KR); Juhyeon Oh, Suwon-si (KR)

(21) Appl. No.: 18/918,605

(22) Filed: Oct. 17, 2024

(30) Foreign Application Priority Data
Dec. 5, 2023 (KR) 10-2023-0174835

(51) Int. Cl. H01L 25/16; G02B 6/122; H01L 23/00; H01L 23/31; H01L 23/367; H01L 23/538; H10B 80/00

(52) U.S. Cl. CPC H01L 25/167; G02B 6/122; H01L 23/367; H01L 23/5385; H01L 24/08; H01L 23/3107; H01L 2224/08145; H10B 80/00

(57) ABSTRACT

A semiconductor package includes a package substrate, an interposer substrate disposed on the package substrate, and a photonics chip structure mounted on the interposer substrate, wherein the photonics chip structure includes an electronic integrated circuit portion including an electronic integrated circuit chip mounted on the interposer substrate, an optical integrated circuit portion including an optical integrated circuit chip having a groove at a corner of an upper portion thereof and mounted on the electronic integrated circuit chip, an edge coupler extending toward the groove, and a waveguide connected to the edge coupler, and a glass connector mounted in the groove of the optical integrated circuit portion and facing the edge coupler.

### CROSS-REFERENCE TO RELATED APPLICATION

This application is based on and claims priority under 35 U.S.C. § 119 to Korean Patent Application No. 10-2023-0174835, filed on Dec. 5, 2023, in the Korean Intellectual Property Office, the disclosure of which is incorporated by reference herein in its entirety.

### BACKGROUND

The inventive concept relates to a semiconductor package, and more particularly, to a semiconductor package including an optical integrated circuit chip.

The advantages of semiconductor packages have been increasingly utilized to improve the functionality of electronic devices and integrate components. Semiconductor packages may allow various ICs, such as memory chips or logic chips, to be mounted on package substrates. Recently, in an environment where data traffic has increased in data centers and communication infrastructures, research on semiconductor packages including optical integrated circuits has continued.

### SUMMARY

The inventive concept provides a semiconductor package that has increased integration and has a shorter electrical signal distance.

According to an aspect of the inventive concept, there is provided a semiconductor package including a package substrate, an interposer substrate disposed on the package substrate, and a photonics chip structure mounted on the interposer substrate, wherein the photonics chip structure includes an electronic integrated circuit portion including an electronic integrated circuit chip mounted on the interposer substrate, an optical integrated circuit portion including an optical integrated circuit chip having a groove at a corner of an upper portion thereof and mounted on the electronic integrated circuit chip, an edge coupler extending toward the groove, and a waveguide connected to the edge coupler, and a glass connector mounted in the groove of the optical integrated circuit portion and facing the edge coupler.

According to another aspect of the inventive concept, there is provided a semiconductor package including a package substrate, an interposer substrate disposed on the package substrate, a photonics chip structure mounted on the interposer substrate, a logic chip structure disposed on the interposer substrate and spaced apart from the photonics chip structure in a horizontal direction, and a memory chip structure disposed to face a side surface of the logic chip structure, wherein the photonics chip structure includes an electronic integrated circuit portion including an electronic integrated circuit chip mounted on the interposer substrate, an optical integrated circuit portion including an optical integrated circuit chip having a groove at a corner of an upper portion thereof and mounted on the electronic integrated circuit chip, an edge coupler disposed to correspond to the groove, and a waveguide connected to the edge coupler, a glass connector mounted in the groove of the optical integrated circuit portion and facing the edge coupler, and a dummy chip disposed on the optical integrated circuit portion to face the glass connector.

According to another aspect of the inventive concept, there is provided a semiconductor package including a package substrate, an interposer substrate disposed on the package substrate, a photonics chip structure mounted on the interposer substrate, a logic chip structure disposed on the interposer substrate and spaced apart from the photonics chip structure in a horizontal direction, a first memory chip structure disposed to face a first side surface of the logic chip structure, and a second memory chip structure facing a second side surface opposite to the first side surface and disposed between the photonics chip structure and the logic chip structure, wherein the photonics chip structure includes a photonics substrate, an electronic integrated circuit portion including an electronic integrated circuit chip mounted on the photonics substrate, an optical integrated circuit portion having a groove at a corner of an upper portion thereof and mounted on the electronic integrated circuit chip, the optical integrated circuit portion including an edge coupler disposed to correspond to the groove and a first waveguide connected to the edge coupler, a glass connector mounted in the groove of the optical integrated circuit portion and facing the edge coupler, and a dummy chip disposed next to the glass connector on the optical integrated circuit portion, the dummy chip having an upper surface on the same plane as a vertical level of an uppermost surface of the logic chip structure, a vertical level of an uppermost surface of the first memory chip structure, and a vertical level of an uppermost surface of the second memory chip structure.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an example embodiment;

FIG. 2 is an enlarged view of an area “CX” shown in FIG. 1; and

FIGS. 3 to 15 are cross-sectional views sequentially illustrating a process of manufacturing a semiconductor package according to an example embodiment.

### DETAILED DESCRIPTION OF THE EMBODIMENTS

Hereinafter, embodiments will be described in detail with reference to the accompanying drawings. However, the inventive concept is not limited to the embodiments described below and may be embodied in various other forms.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

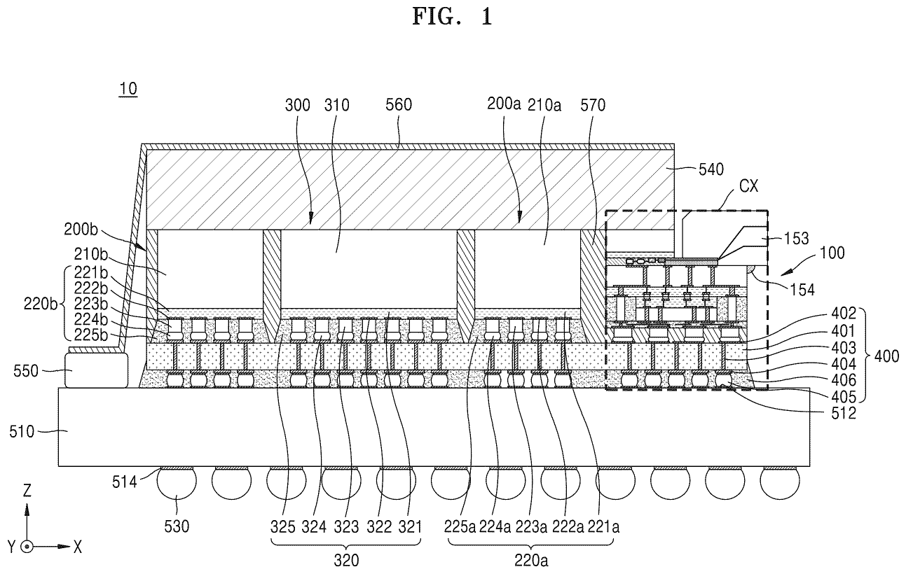

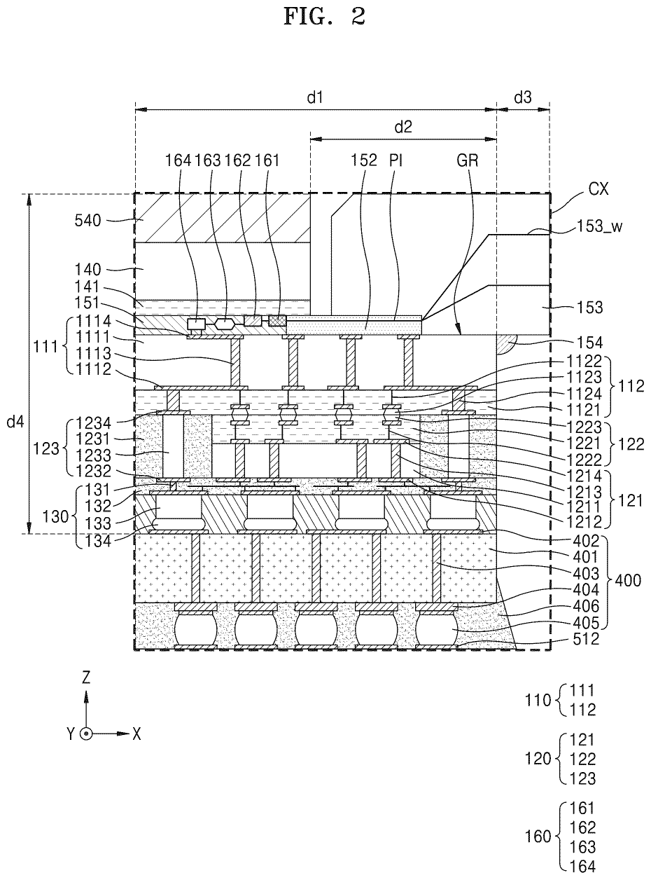

FIG. 1 is a cross-sectional view of a semiconductor package 10 according to an embodiment, and FIG. 2 is an enlarged view of an area “CX” shown in FIG. 1.

Referring to FIGS. 1 and 2, the semiconductor package 10 according to an embodiment may include a photonics chip structure 100, a first memory chip structure 200a, a second memory chip structure 200b, a logic chip structure 300, and an interposer 400. In addition, the semiconductor package 10 may include a package substrate 510, package upper pads 512, package lower pads 514, package connection terminals 530, a heat dissipation member 540, an adhesive member 550, a lead frame 560, and a molding layer 570.

The photonics chip structure 100 will be described in detail later, and other components will be described first. Hereinafter, unless specifically defined, a direction parallel to the upper surface of the package substrate 510 is defined as a first horizontal direction (an X direction), a direction perpendicular to the upper surface of the package substrate 510 is defined as a vertical direction (a Z direction), and a direction perpendicular to the first horizontal direction (the X direction) and the vertical direction (the Z direction) is defined as a second horizontal direction (a Y direction). A direction obtained by combining the first horizontal direction (the X direction) with the second horizontal direction (the Y direction) is defined as a horizontal direction.

The package substrate 510 may be, for example, a printed circuit board (PCB). The package substrate 510 may have an upper surface having an area sufficient to accommodate the interposer 400. The package substrate 510 may include a core insulating layer including at least one material selected from phenol resin, epoxy resin, and polyimide. For example, the core insulating layer may include at least one selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The package upper pads 512 may be located on the upper surface of the package substrate 510, and the package lower pads 514 may be located on the lower surface of the package substrate 510. For example, the package upper pads 512 may contact an upper surface of the package substrate 510, and the package lower pads 514 may contact a lower surface of the package substrate 510. The package upper pads 512 and the package lower pads 514 may be part of a circuit wiring line patterned after the upper and lower surfaces of the package substrate 510 are coated with copper (Cu) foil. Specifically, the package upper pads 512 and the package lower pads 514 may be areas of the circuit wiring line that are not covered by a solder resist layer and are exposed to the outside.

In some embodiments, the package upper pads 512 and the package lower pads 514 may each be formed of or include copper, nickel, stainless steel, or beryllium copper. Internal wiring lines may be formed within the package substrate 510 to electrically connect the package upper pads 512 to the package lower pads 514.

The package connection terminals 530 may be attached to the package lower pads 514. For example, each of the package connection terminals 530 may contact a respective one of the package lower pads 514. The package connection terminals 530 may be configured to electrically and physically connect the package substrate 510 to an external device on which the package substrate 510 is mounted. The package connection terminals 530 may be formed from, for example, solder balls or solder bumps.

According to an embodiment, the interposer 400 may include an interposer substrate 401, interposer upper pads 402, interposer through-electrodes 403, interposer lower pads 404, interposer connection terminals 405, and an interposer terminal protection layer 406.

In an example embodiment, the interposer 400 may be disposed between the package substrate 510 and a plurality of chip structures (e.g., the first memory chip structure 200a, the second memory chip structure 200b, the logic chip structure 300, and the photonics chip structures 100) and may be configured to electrically connect the plurality of chip structures to each other. That is, the first memory chip structure 200a, the second memory chip structure 200b, the logic chip structure 300, and the photonics chip structure 100 may transmit/receive electrical signals to/from each other through the interposer 400.

For example, the material of the interposer substrate 401 may include silicon (Si). However, the inventive concept is not limited thereto, and the interposer substrate 401 may include a semiconductor element, such as germanium, or may also include a semiconductor compound, such as silicon carbide (SiC), gallium arsenide (GaAs), indium arsenide (InAs), or indium phosphide (InP).

The interposer upper pads 402 may be disposed on the upper surface of the interposer substrate 401 and connected to an upper portion of the interposer through-electrodes 403. For example, each interposer upper pad 402 may contact the upper surface of the interposer substrate 401 and an upper surface of a corresponding one of the interposer through-electrodes 403. In an example embodiment, the interposer upper pads 402 may be pads for electrically connecting a semiconductor chip mounted on the interposer 400 with the interposer through-electrodes 403.

In addition, the interposer lower pads 404 may be disposed on the lower surface of the interposer substrate 401 and connected to a lower portion of the interposer through-electrodes 403. For example, the interposer lower pads 404 may be contact the lower surface of the interposer substrate 401 and a lower surface of a corresponding one of the interposer through-electrodes 403. In an example embodiment, the interposer lower pads 404 may be pads for attaching the interposer connection terminals 405 thereto.

In an example embodiment, the interposer upper pads 402 and the interposer lower pads 404 may be formed of or include aluminum (Al). However, the inventive concept is not limited to the above, and the interposer upper pads 402 and the interposer lower pads 404 may be formed of or include a metal, such as nickel (Ni), copper (Cu), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or an alloy thereof.

The interposer connection terminals 405 may be terminals for electrically connecting the interposer 400 to a semiconductor chip disposed below the interposer 400. In an example embodiment, each interposer connection terminal 405 may be a solder ball made of a metal material including at least one of Sn, Ag, Cu, and Al.

The interposer through-electrodes 403 may pass through at least a portion of the interposer substrate 401 in the vertical direction (the Z direction). For example, the interposer through-electrodes 403 may pass through the upper and lower surfaces of the interposer substrate 401 in the vertical direction (Z direction). For example, upper surfaces of the interposer through-electrodes 403 may be coplanar with an upper surface of the interposer substrate 401, and lower surfaces of the interposer through-electrodes 403 may be coplanar with a lower surface of the interposer substrate 401.

In an example embodiment, each of the interposer through-electrodes 403 may have a cylindrical shape. For example, the interposer through-electrode 403 may have a cylindrical shape whose width in the horizontal direction (e.g., the first horizontal direction (the X direction) and/or the second horizontal direction (the Y direction)) is substantially the same along the vertical direction (the Z direction).

However, the inventive concept is not limited thereto, and the interposer through-electrode 403 may have a tapered shape whose width in the horizontal direction (e.g., the first horizontal direction (the X direction) and/or the second horizontal direction (the Y direction)) gradually decreases as it moves away from the upper surface of the interposer through-electrode 403 in the vertical direction (the Z direction).

In an example embodiment, although not shown in FIG. 1, the interposer through-electrode 403 may include a seed layer (not shown) conformally disposed along the surface of the interposer through-electrode 403, and a conductive layer (not shown) disposed on the seed layer.

For example, the conductive layer may include a metal material. For example, the conductive layer may be formed of or include at least one of Al, Au, Be, Bi, Co, Cu, Hf, In, Mn, Mo, Ni, Pb, Pd, Pt, Rh, Re, Ru, Ta, Te, Ti, W, Zn, and Zr.

The interposer terminal protection layer 406 may be disposed between the interposer substrate 401 and the package substrate 510 and surround the interposer connection terminal 405. The interposer terminal protection layer 406 may contact an upper surface of the package substrate 510, side and upper surfaces of the package upper pads 512, side and lower surfaces of the interposer lower pads 404, and lower and side surfaces of the interposer substrate 401. The interposer terminal protection layer 406 may include epoxy resin formed by, for example, a capillary under-fill method. In example embodiments, the interposer terminal protection layer 406 may be a non-conductive film (NCF).

The photonics chip structure 100, the first memory chip structure 200a, the second memory chip structure 200b, and the logic chip structure 300 may be mounted on the upper surface of the interposer 400. The photonics chip structure 100 may be located on an outer portion of the upper surface of the interposer 400. The photonics chip structure 100, the first memory chip structure 200a, the second memory chip structure 200b, and the logic chip structure 300 may be arranged to be at the same vertical level on the interposer 400. For example, the uppermost surface of the photonics chip structure 100, the uppermost surface of the first memory chip structure 200a, the uppermost surface of the second memory chip structure 200b, and the uppermost surface of the logic chip structure 300 may all be located on the same plane.

According to an embodiment, the logic chip structure 300 may be disposed adjacent to the center of the upper surface of the interposer substrate 401, and the first memory chip structure 200a and the second memory chip structure 200b may be arranged to be spaced apart from each other in the first horizontal direction (the X direction) with the logic chip structure 300 therebetween. In this case, the separation distance between the logic chip structure 300 and the first memory chip structure 200a in the first horizontal direction (the X direction) may be substantially the same as the separation distance between the logic chip structure 300 and the second memory chip structure 200b in the first horizontal direction (the X direction).

The first memory chip structure 200a may include a first memory chip 210a and a first wiring structure 220a. The first memory chip 210a may be a memory chip, such as high bandwidth memory (HBM). Alternatively, the first memory chip 210a may be a memory chip, such as volatile memory (e.g., DRAM), non-volatile memory (e.g., ROM), or flash memory (e.g., NAND Flash). Likewise, the second memory chip structure 200b may include a second memory chip 210b and a second wiring structure 220b. The second memory chip structure 200b may be a memory chip, such as high bandwidth memory (HBM). Alternatively, the second memory chip structure 200b may be a memory chip, such as volatile memory (e.g., DRAM), non-volatile memory (e.g., ROM), or flash memory (e.g., NAND Flash).

In some embodiments, each of the first memory chip 210a and the second memory chip 210b may be mounted on the interposer 400 with an inactive surface facing upward and an active surface facing downward. As used herein, the “inactive surface” may be the surface which does not include any devices, and the “active surface” may be the surface on which devices are formed. As described below, the first memory chip 210a and the second memory chip 210b may be electrically connected to the interposer 400 through the first connection terminals 224a and the second connection terminals 224b, respectively.

In some embodiments, a plurality of various types of individual devices may be located on the active surfaces of the first memory chip 210a and the second memory chip 210b. For example, the plurality of individual devices may include various microelectronic devices, such as a complementary metal-oxide semiconductor (CMOS) transistor, a metal-oxide-semiconductor field effect transistor (MOSFET), a system large scale integration (LSI), an image sensor, such as a CMOS image sensor (CIS), a micro-electro-mechanical system (MEMS), an active device, and a passive device.

The first wiring structure 220a may be configured to provide an electrical connection path between the first memory chip 210a and the interposer 400. Likewise, the second wiring structure 220b may be configured to provide an electrical connection path between the second memory chip 210b and the interposer 400. In this case, when the electrical connection paths provided by the first wiring structure 220a and the second wiring structure 220b are physically expressed, the electrical connection paths may be connection paths in the vertical direction (the Z direction).

The first wiring structure 220a may include a first redistribution layer 221a, first lower pads 222a, first connection conductors 223a, first connection terminals 224a, and a first underfill resin 225a. The second wiring structure 220b may include a second redistribution layer 221b, second lower pads 222b, second connection conductors 223b, second connection terminals 224b, and a second underfill resin 225b.

The first redistribution layer 221a and the second redistribution layer 221b may each be, for example, a printed circuit board (PCB). In some embodiments, the first redistribution layer 221a and the second redistribution layer 221b may each be referred to as a package substrate. Each of the first redistribution layer 221a and the second redistribution layer 221b may include a core insulating layer including at least one material selected from phenol resin, epoxy resin, and polyimide. For example, the core insulating layer may include at least one selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The first lower pads 222a may be disposed on the lower surface of the first redistribution layer 221a. For example, the first lower pads 222a may contact the lower surface of the first redistribution layer 221a. In this case, conductive patterns that physically and electrically connect the first memory chip 210a to the first lower pad 222a may be disposed in the first redistribution layer 221a. In this case, the conductive patterns may include a plurality of horizontal patterns extending in the horizontal direction (e.g., the first horizontal direction (the X direction) and/or the second horizontal direction (the Y direction)) and having different vertical levels, and conductive vias which are disposed between the horizontal patterns having different vertical levels and extend in the vertical direction (the Z direction).

Likewise, the second lower pads 222b may be disposed on the lower surface of the second redistribution layer 221b. For example, the second lower pads 222b may contact the lower surface of the second redistribution layer 221b. In this case, conductive patterns that physically and electrically connect the second memory chip 210b to the second lower pads 222b may be disposed in the second redistribution layer 221b. In this case, the conductive patterns may include a plurality of horizontal patterns extending in the horizontal direction (e.g., the first horizontal direction (the X direction) and/or the second horizontal direction (the Y direction)) and having different vertical levels, and conductive vias which are disposed between the horizontal patterns having different vertical levels and extend in the vertical direction (the Z direction).

The first connection conductors 223a and the second connection conductors 223b may be configured to physically and electrically connect the first lower pads 222a to the first connection terminals 224a and the second lower pads 222b to the second connection terminals 224b, respectively. The first connection conductors 223a and the second connection conductors 223b may each have a circular pillar shape extending in the vertical direction (the Z direction). In this case, the lengths of the first connection conductors 223a and the second connection conductors 223b in the vertical direction (the Z direction) may be relatively greater than the thicknesses of the first lower pads 222a and the second lower pads 222b in the vertical direction (the Z direction), respectively.

For example, the first lower pads 222a, the second lower pads 222b, the first connection conductors 223a, and the second connection conductors 223b may be formed of or include a metal material. For example, the metal material may include at least one of Al, Au, Be, Bi, Co, Cu, Hf, In, Mn, Mo, Ni, Pb, Pd, Pt, Rh, Re, Ru, Ta, Te, Ti, W, Zn, and Zr.

The first connection terminals 224a and the second connection terminals 224b may be disposed between the first connection conductors 223a and the interposer upper pad 402 and between the second connection conductors 223b and the interposer upper pad 402, respectively. The first connection terminals 224a may be terminals for electrically connecting the first memory chip structure 200a to the interposer 400, and the second connection terminals 224b may be terminals for electrically connecting the second memory chip structure 200b to the interposer 400. In an example embodiment, the first connection terminals 224a and the second connection terminals 224b may be solder balls including a metal material including at least one of Sn, Ag, Cu, and Al.

The first underfill resin 225a may be disposed between the interposer substrate 401 of the interposer 400 and the first redistribution layer 221a of the first memory chip structure 200a and may surround the first connection conductors 223a and the first connection terminals 224a. For example, the first underfill resin 225a may contact side surfaces of the first connection conductors 223a and the first connection terminals 224a. The second underfill resin 225b may be disposed between the interposer substrate 401 of the interposer 400 and the second redistribution layer 221b of the second memory chip structure 200b and may surround the second connection conductors 223b and the second connection terminals 224b. For example, the first underfill resin 225a may contact side surfaces of the second connection conductors 223b and the second connection terminals 224b. The first underfill resin 225a and the second underfill resin 225b may include epoxy resin formed by, for example, a capillary under-fill method. In example embodiments, the first underfill resin 225a and the second underfill resin 225b may be NCFs.

The logic chip structure 300 may include a logic chip 310 and a third wiring structure 320. The logic chip 310 may include an application processor chip, such as a central processor (e.g., a central processing unit (CPU)), a graphics processor (e.g., a graphics processor unit (GPU)), a digital signal processor, a cryptographic processor, a microprocessor, and a microcontroller, and a chip, such as an analog-to-digital converter and an application-specific integrated circuit (ASIC).

The third wiring structure 320 may be configured to provide an electrical connection path between the logic chip 310 and the interposer 400. In this case, when the electrical connection path provided by the third wiring structure 320 is physically expressed, the electrical connection path may be a connection path in the vertical direction (the Z direction).

The third wiring structure 320 may include a third redistribution layer 321, third lower pads 322, third connection conductors 323, third connection terminals 324, and a third underfill resin 325. The third wiring structure 320 may have a structure similar to that of the first wiring structure 220a or the second wiring structure 220b.

The third redistribution layer 321 may be, for example, a PCB. In some embodiments, the third redistribution layer 321 may be referred to as a package substrate. Because a material of the third redistribution layer 321 is substantially the same as those of the first redistribution layer 221a and the second redistribution layer 221b, the detailed description thereof is omitted.

The third lower pads 322 may be disposed on the lower surface of the third redistribution layer 321. For example, the third lower pads 322 may contact the lower surface of the third redistribution layer 321. In this case, conductive patterns that physically and electrically connect the logic chip 310 to the third lower pads 322 may be disposed in the third redistribution layer 321. In this case, the conductive patterns may include a plurality of horizontal patterns extending in the horizontal direction (e.g., the first horizontal direction (the X direction) and/or the second horizontal direction (the Y direction)) and having different vertical levels, and conductive vias which are disposed between the horizontal patterns having different vertical levels and extend in the vertical direction (the Z direction).

The third connection conductors 323 may be configured to physically and electrically connect the third lower pads 322 to the third connection terminals 324. The third connection conductors 323 may have a circular pillar shape extending in the vertical direction (the Z direction). In this case, the length of the third connection conductors 323 in the vertical direction (the Z direction) may be relatively greater than the thickness of the third lower pads 322 in the vertical direction (the Z direction).

For example, the third lower pads 322 and the third connection conductors 323 may include a metal material. For example, the metal material may include at least one of Al, Au, Be, Bi, Co, Cu, Hf, In, Mn, Mo, Ni, Pb, Pd, Pt, Rh, Re, Ru, Ta, Te, Ti, W, Zn, and Zr.

The third connection terminals 324 may be disposed between the third connection conductors 323 and the interposer upper pads 402. The third connection terminals 324 may be terminals for electrically connecting the logic chip structure 300 to the interposer 400. In an example embodiment, each of the third connection terminals 324 may be a solder ball including a metal material including at least one of Sn, Ag, Cu, and Al.

The third underfill resin 325 may be disposed between the interposer substrate 401 of the interposer 400 and the third redistribution layer 321 of the logic chip structure 300 and may surround the third connection conductors 323 and the third connection terminals 324. For example, the third underfill resin 325 may contact side surfaces of the third connection conductors 323 and the third connection terminals 324. The third underfill resin 325 may include epoxy resin formed by, for example, a capillary under-fill method. In example embodiments, the third underfill resin 325 may be an NCF.

According to an embodiment, the heat dissipation member 540 may be bonded to the uppermost surface of the photonics chip structure 100, the uppermost surface of the first memory chip structure 200a, the uppermost surface of the second memory chip structure 200b, and the uppermost surface of the logic chip structure 300. For example, the heat dissipation member 540 may be bonded to the uppermost surface of a dummy chip 140, the uppermost surface of the first memory chip 210a, the uppermost surface of the second memory chip 210b, and the uppermost surface of the logic chip 310. As described below, the molding layer 570 may be disposed between the photonics chip structure 100, the first memory chip structure 200a, the second memory chip structure 200b, and the logic chip structure 300 on the upper surface of the interposer 400, and the heat dissipation member 540 may also be bonded to the upper surface of the molding layer 570. According to an embodiment, the heat dissipation member 540 may not be directly bonded to a plurality of chips, but an adhesive material may be disposed between the heat dissipation member 540 and the plurality of chips.

For example, the heat dissipation member 540 may be formed of or include a thermal interface material (TIM). The TIM may include a thermal grease, a thermal sheet/film, a thermal pad, and a thermal adhesive. The TIM may include a filler having excellent thermal conductivity, for example, aluminum oxide (Al₂O₃), silver, silicon dioxide (SiO₂), aluminum nitride (AlN), or boron nitride (BN).

The heat dissipation member 540 may be arranged to cover almost all of the upper surfaces of the first memory chip structure 200a, the second memory chip structure 200b, and the logic chip structure 300. However, the heat dissipation member 540 may have an area smaller than the area of the upper surface of the interposer substrate 401. This is because the heat dissipation member 540 does not overlap the entire upper surface of the photonics chip structure 100. A portion of the upper surface of the photonics chip structure 100 is covered by a glass connector 153, and the glass connector 153 is not in contact with the heat dissipation member 540 and is spaced apart from the heat dissipation member 540 in the horizontal direction (e.g., the first horizontal direction (the X direction) and/or the second horizontal direction (the Y direction)) and thus may have an area that is less than the area of the upper surface of the interposer substrate 401. As described below, the upper surface of the glass connector 153 protrudes in the vertical direction (the Z direction) when compared to the upper surfaces of the other plurality of chips (i.e., the first memory chip 210a, the second memory chip 210b, and the logic chip 310), and thus, for structural stability, the heat dissipation member 540 does not overlap the upper surface of the glass connector 153. For example, the upper surface of the glass connector 153 may be at a higher vertical level in the Z direction than the upper surfaces of the other plurality of chips (i.e., the first memory chip 210a, the second memory chip 210b, and the logic chip 310).

According to an embodiment, the area of a portion of the total area of the upper surface of the photonics chip structure 100 that does not overlap the heat dissipation member 540 may range from about 2% to about 80% of the total area. For example, as shown in FIG. 2, of a lateral distance d1 of the photonics chip structure 100, a lateral distance d2 of the portion that does not overlap the heat dissipation member 540 may be in the range of about 2% to about 80% of the lateral distance d1.

The lead frame 560 may be attached on the heat dissipation member 540. The lead frame 560 may completely cover the upper surface of the heat dissipation member 540 and may be configured to protect the side surface of the heat dissipation member 540, the side surface of the molding layer 570, and the side surface of the interposer 400 from the outside. The upper surface of the lead frame 560 may be flat in the horizontal direction (e.g., the first horizontal direction (the X direction) and/or the second horizontal direction (the Y direction)). The lead frame 560 may contact an upper surface of the heat dissipation member 540. A side portion of the lead frame 560 may be inclined at a constant inclination from the vertical direction (the Z direction). In this case, a separation distance between the side portion of the lead frame 560 and the molding layer 570 increases as it approaches the package substrate 510. The side portion of the lead frame 560 extending obliquely may be in contact with the upper surface of the adhesive member 550, and a portion of the lead frame 560 in contact with the adhesive member 550 may again have a flat shape in the horizontal direction (e.g., the first horizontal direction (the X direction) and/or the second horizontal direction (the Y direction)). An opposite side of a portion leading to the side portion of the lead frame 560 that is inclined obliquely from the vertical direction (the Z direction) may no longer extend beyond the side wall of the heat dissipation member 540. That is, because the lead frame 560 does not overlap the glass connector 153, a surface opposite to the side portion of the lead frame 560 may have the same plane as the side wall of the heat dissipation member 540. The lead frame 560 may be formed of or include, for example, Cu.

The adhesive member 550 may be disposed on an outer edge of the upper surface of the package substrate 510. In this case, the adhesive member 550 may be disposed further outside the interposer 400 on the upper surface of the package substrate 510. The adhesive member 550 may be configured to attach the lead frame 560 to the package substrate 510. The adhesive member 550 may be disposed only on one side of an outer edge of the package substrate 510.

The molding layer 570 may be disposed on the interposer substrate 401 and may be a layer surrounding the first memory chip structure 200a, the second memory chip structure 200b, the logic chip structure 300, and the photonics chip structure 100.

In an example embodiment, the molding layer 570 may be formed of or include a material of epoxy molding compound (EMC). However, the material of the molding layer 570 is not limited to the EMC and may include various materials, such as epoxy-based materials, thermosetting materials, thermoplastic materials, or UV treated materials.

In an example embodiment, the molding layer 570 may cover side portions of the first memory chip structure 200a, the second memory chip structure 200b, and the logic chip structure 300. For example, the molding layer 570 may contact side surfaces of the first memory chip structure 200a, the second memory chip structure 200b, and the logic chip structure 300. In addition, the upper surface of the molding layer 570 may be on the same plane as the upper surface of the first memory chip 210a, the upper surface of the second memory chip 210b, and the upper surface of the logic chip 310. Because the upper surface of the molding layer 570 may be on the same plane as the upper surfaces of the plurality of semiconductor chips, the semiconductor package 10 may be made thin and light. However, the inventive concept is not limited thereto and the level of the upper surface of the molding layer 570 may be higher than the levels of the upper surfaces of the plurality of semiconductor chips.

According to an embodiment, the photonics chip structure 100 may include an optical integrated circuit portion 110, an electronic integrated circuit portion 120, a photonics wiring structure 130, and a dummy chip 140. In addition, the photonics chip structure 100 may include, a second insulating layer 141, a waveguide 151, an edge coupler 152, a glass connector 153, an adhesive layer 154, a photodetector 161, a photodiode 162, an amplifier 163, and a modulator 164, which are on the optical integrated circuit portion 110.

For convenience of explanation, the photonics wiring structure 130 and the electronic integrated circuit portion 120 will be described first.

According to an embodiment, the photonics wiring structure 130 may include a conductive pattern 131, a first insulating layer 132, chip connection conductors 133, and chip connection terminals 134. The photonics wiring structure 130 may be configured to electrically and physically connect the interposer 400 to the photonics chip structure 100.

The first insulating layer 132 may be located on an active surface, that is, the lower surface, of the electronic integrated circuit portion 120. The first insulating layer 132 may have a constant thickness and extend in the horizontal direction (the X direction and/or the Y direction). The first insulating layer 132 may include at least one selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The conductive pattern 131 may include a plurality of horizontal conductive patterns extending in the horizontal direction (the X direction and/or the Y direction) within the first insulating layer 132 and having different vertical levels, and vertical vias extending in the vertical direction (the Z direction) and connecting the plurality of horizontal conductive patterns having different vertical levels. Some of the conductive patterns 131 may be disposed on the lower surface of the first insulating layer 132 and function as a pad bonded to the chip connection conductor 133. In addition, some of the conductive patterns 131 may be disposed on the upper surface of the first insulating layer 132 and function as a pad bonded to a vertical connection conductor 1233 and an electronics integrated circuit (EIC) through-electrode 1213. That is, the conductive pattern 131 may be configured to electrically connect the electronic integrated circuit portion 120 to the chip connection conductor 133.

The chip connection conductors 133 may be configured to physically and electrically connect the conductive pattern 131 to the chip connection terminals 134. The chip connection conductors 133 may have a circular pillar shape extending in the vertical direction (the Z direction). In this case, the length of the chip connection conductors 133 in the vertical direction (the Z direction) may be relatively greater than the thickness of the horizontal conductive pattern of the conductive pattern 131 in the vertical direction (the Z direction).

For example, the conductive pattern 131 and the chip connection conductors 133 may include a metal material. For example, the metal material may include at least one of Al, Au, Be, Bi, Co, Cu, Hf, In, Mn, Mo, Ni, Pb, Pd, Pt, Rh, Re, Ru, Ta, Te, Ti, W, Zn, and Zr.

The chip connection terminals 134 may be disposed between the chip connection conductors 133 and the interposer upper pads 402. The chip connection terminals 134 may be terminals for electrically connecting the photonics chip structure 100 to the interposer 400. In an example embodiment, each chip connection terminal 134 may be a solder ball including a metal material including at least one of Sn, Ag, Cu, and Al.

According to an embodiment, the electronic integrated circuit portion 120 may include an electronic integrated circuit chip 121, an EIC wiring portion 122, and a vertical connection portion 123.

The electronic integrated circuit chip 121 may include a second substrate 1211, EIC lower pads 1212, EIC through-electrodes 1213, and EIC upper pads 1214.

The electronic integrated circuit portion 120 may be stacked on the photonics wiring structure 130. The second substrate 1211 may include a semiconductor material, such as silicon (Si). Alternatively, the second substrate 1211 may include a semiconductor material, such as germanium (Ge).

The second substrate 1211 may include an active surface on which a plurality of individual devices are formed and an inactive surface opposite to the active surface. In this case, the active surface is the lower surface of the second substrate 1211, and the inactive surface is the upper surface of the second substrate 1211. The lower surface of the second substrate 1211 may face the interposer 400. The EIC lower pads 1212 may be located on the active surface of the second substrate 1211, and the EIC upper pads 1214 may be located on the inactive surface of the second substrate 1211. For example, the EIC lower pads 1212 may contact the active surface of the second substrate 1211, and the EIC upper pads 1214 may contact the inactive surface of the second substrate 1211. The EIC through-electrodes 1213 may pass through the second substrate 1211 and extend from the active surface to the inactive surface. In this case, a lower end of the EIC through-electrode 1213 may be physically and electrically connected to a corresponding one of the EIC lower pads 1212, and an upper end of the EIC through-electrode 1213 may be physically and electrically connected to a corresponding one of the EIC upper pads 1214. For example, the lower end of the EIC through-electrode 1213 may contact an upper surface of a corresponding one of the EIC lower pads 1212, and the upper end of the EIC through-electrode 1213 may contact a lower surface of a corresponding one of the EIC upper pads 1214. In some embodiments, the EIC through-electrodes 1213 may be electrically connected to the plurality of individual devices on the active surface of the second substrate 1211.

The electronic integrated circuit chip 121 may be arranged to face the interposer 400 of the second substrate 1211. For example, the electronic integrated circuit chip 121 may be disposed on the photonics wiring structure 130 in a face down manner.

The EIC wiring portion 122 may be located on an inactive surface, that is, the upper surface, of the electronic integrated circuit chip 121. The EIC wiring portion 122 may include an EIC insulating layer 1221, an EIC conductive pattern 1222, and EIC conductive pads 1223. The EIC insulating layer 1221 may have a constant thickness and be formed along the upper surface of the electronic integrated circuit chip 121. The EIC insulating layer 1221 may include at least one selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The EIC conductive pattern 1222 may include a plurality of horizontal conductive patterns extending in the horizontal direction (the X direction and/or the Y direction) within the EIC insulating layer 1221 and having different vertical levels, and vertical vias extending in the vertical direction (the Z direction) and connecting the plurality of horizontal conductive patterns having different vertical levels. That is, the EIC conductive pattern 1222 may be configured to electrically connect the EIC upper pads 1214 of the electronic integrated circuit chip 121 to the EIC conductive pads 1223.

The EIC conductive pads 1223 may be disposed to be exposed on the upper surface of the EIC insulating layer 1221 and may have a thickness greater than that of the EIC conductive pattern 131. The EIC conductive pads 1223 may be formed of or include Cu. As described below, the EIC conductive pads 1223 may be hybrid-bonded to photonics integrated circuit (PIC) conductive pads 1123.

The vertical connection portion 123 may include an outer insulating layer 1231, a first intermediate conductive pattern layer 1232, vertical connection conductors 1233, and a second intermediate conductive pattern layer 1234. The vertical connection conductors 1233 may extend from the upper surface of the outer insulating layer 1231 to the lower surface thereof. A lower surface of each of the vertical connection conductor 1233 may contact the first intermediate conductive pattern layer 1232, and an upper surface of each of the vertical connection conductor 1233 may contact the second intermediate conductive pattern layer 1234. The first intermediate conductive pattern layer 1232 may contact a lower surface of the outer insulating layer 1231, and the second intermediate conductive pattern layer 1234 may contact an upper surface of the outer insulating layer 1231.

According to an embodiment, the optical integrated circuit portion 110 may include an optical integrated circuit chip 111 and a PIC wiring portion 112. The optical integrated circuit chip 111 may include a first substrate 1111, PIC lower pads 1112, PIC through-electrodes 1113, and PIC upper pads 1114, and the PIC wiring portion 112 may include a PIC insulating layer 1121, a PIC conductive pattern 1122, PIC conductive pads 1123, and outer conductors 1124.

The optical integrated circuit portion 110 may be stacked on the electronic integrated circuit portion 120. The first substrate 1111 may include a semiconductor material, such as Si. Alternatively, the first substrate 1111 may include a semiconductor material, such as Ge.

The first substrate 1111 may include an active surface on which a plurality of individual devices are formed and an inactive surface opposite to the active surface. In this case, the active surface is the upper surface of the first substrate 1111, and the inactive surface is the lower surface of the first substrate 1111. The lower surface of the first substrate 1111 may face the electronic integrated circuit portion 120. The PIC lower pads 1112 may be located on the inactive surface of the first substrate 1111, and the PIC upper pads 1114 may be located on the active surface of the first substrate 1111. For example, the PIC lower pads 1112 may contact the inactive surface of the first substrate 1111, and the PIC upper pads 1114 may contact the active surface of the first substrate 1111. The PIC through-electrodes 1113 may pass through the first substrate 1111 and extend from the active surface to the inactive surface. In this case, for each of the PIC through-electrodes 1113, a lower end of the PIC through-electrode 1113 may be physically and electrically connected to a corresponding one of the PIC lower pads 1112, and an upper end of the PIC through-electrode 1113 may be physically and electrically connected to a corresponding one of the PIC upper pads 1114. In some embodiments, the PIC through-electrodes 1113 may be electrically connected to the plurality of individual devices on the active surface of the first substrate 1111.

The optical integrated circuit chip 111 may be arranged such that the active surface of the first substrate 1111 faces the glass connector 153. For example, the optical integrated circuit chip 111 may be disposed on the PIC wiring portion 112 in a face up manner. The area of the upper surface of the optical integrated circuit chip 111 may be greater than the area of the upper surface of the electronic integrated circuit chip 121. Because the electronic integrated circuit chip 121 is surrounded by the vertical connection portion 123, from a horizontal perspective, the area of the upper surface of the optical integrated circuit chip 111 may be the sum of the area of the upper surface of the electronic integrated circuit chip 121 and the area including the upper surfaces of the vertical connection portion 123. Even when the electronic integrated circuit chip 121 having a narrow planar area is placed below the optical integrated circuit chip 111 having a wide planar area, the vertical connection portion 123 may be arranged to surround the perimeter of the electronic integrated circuit chip 121 to maintain structural stability.

The PIC wiring portion 112 may be located on an inactive surface, that is, the lower surface, of the optical integrated circuit chip 111. The PIC wiring portion 112 may include a PIC insulating layer 1121, a PIC conductive pattern 1122, and PIC conductive pads 1123. The PIC insulating layer 1121 may have a constant thickness and be formed along the upper surface of the electronic integrated circuit chip 121. The PIC insulating layer 1121 may include at least one selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The PIC conductive pattern 1122 may include a plurality of horizontal conductive patterns extending in the horizontal direction (the X direction and/or the Y direction) within the PIC insulating layer 1121 and having different vertical levels, and vertical vias extending in the vertical direction (the Z direction) and connecting the plurality of horizontal conductive patterns having different vertical levels. For example, the PIC conductive pattern 1122 may be configured to electrically connect the PIC upper pads 1114 of the optical integrated circuit chip 111 to the PIC conductive pads 1123.

The PIC conductive pads 1123 may be disposed to be exposed on the upper surface of the PIC insulating layer 1121 and may have a thickness greater than that of the PIC conductive pattern 1122. The PIC conductive pads 1123 may be formed of or include Cu.

According to an embodiment, the lower surface of the PIC insulating layer 1121 and the upper surface of the EIC insulating layer 1221 may be directly bonded to each other. In addition, the lower surface of each PIC conductive pad 1123 may be directly bonded to the upper surface of a corresponding one of the EIC conductive pads 1223. Simultaneous bonding of the insulating layers 1121 and 1221 and the conductive pads 1123 and 1223 may be referred to as hybrid bonding. The hybrid bonding may be performed by heat-treating the insulating layers 1121 and 1221 and the conductive pads 1123 and 1223 while they are attached to each other.

An optical-electrical conversion portion 160 and a waveguide 151 may be disposed on an upper portion of the optical integrated circuit chip 111. The optical-electrical conversion portion 160 of the optical integrated circuit chip 111 may convert optical signals into electrical signals and electrical signals into optical signals. In some embodiments, the optical-electrical conversion portion 160 may include a photodetector 161, a photodiode 162, an amplifier 163, and a modulator 164.

A groove GR may be formed in an upper corner of the optical integrated circuit chip 111. The groove GR may be recessed inward from the side and upper surfaces of the optical integrated circuit chip 111. For example, the groove GR may be recessed from the upper surface of the optical integrated circuit chip 111 to the inside, and the inside of the groove GR may be open toward the side surface of the optical integrated circuit chip 111.

In some embodiments, the groove GR may be referred to as a V-groove. When the groove GR is viewed from the side surface of the optical integrated circuit chip 111, the cross-section of the groove GR may have a shape in which V-shaped grooves are arranged with some overlap along the side surface of the optical integrated circuit chip 111. In some embodiments, the glass connector 153 may be mounted in V-shaped grooves.

In the process of inputting an optical signal to the optical integrated circuit chip 111, the photodetector 161 may detect the optical signal input to the optical integrated circuit chip 111. The optical integrated circuit chip 111 may detect an optical signal through the photodetector 161 and convert the optical signal into an electrical signal. The electrical signal converted by the photodetector 161 may be transmitted to a plurality of individual devices on the active surface of the second substrate 1211 of the optical integrated circuit chip 111.

In the process of the optical integrated circuit chip 111 outputting an optical signal, the plurality of individual elements on the active surface of the second substrate 1211 of the optical integrated circuit chip 111 may each transmit an electrical signal to the modulator 164. The modulator 164 may convert the electrical signal into an optical signal by inputting a signal into light emitted by the photodiode 162 according to the electrical signal.

The waveguide 151 may be a path through which an optical signal moves in the optical integrated circuit chip 111. The waveguide 151 may be a path through which an optical signal transmitted to the edge coupler 152 moves to the photodetector 161, or may be a path through which an optical signal converted by the modulator 164 moves to the edge coupler 152. For example, an optical signal may move in a horizontal direction from the top of the optical integrated circuit chip 111 along the waveguide 151.

The optical integrated circuit portion 110 may include the edge coupler 152 extending toward the groove GR on the active surface of the second substrate 1211, and the waveguide 151 connected to the edge coupler 152.

The waveguide 151 may be a path through which an optical signal moves in the optical integrated circuit portion 110. The waveguide 151 may be a path through which an optical signal transmitted to the edge coupler 152 moves to the photodetector 161, or may be a path through which an optical signal converted by the modulator 164 moves to the edge coupler 152. For example, an optical signal may move in a horizontal direction on the top surface of the optical integrated circuit chip 111 along the waveguide 151.

The edge coupler 152 may be a portion of the waveguide 151. For example, the edge coupler 152 may be an area of the waveguide 151 on which an optical signal coming through the glass connector 153 is incident. The edge coupler 152 may be an area that emits an optical signal from the waveguide 151 to the glass connector 153.

In some embodiments, the waveguide 151 may be arranged such that the edge coupler 152 faces the groove GR. That is, the edge coupler 152 may be located at an end of the waveguide 151 adjacent to the groove GR.

In some embodiments, the edge coupler 152 may have a different horizontal width from other areas of the waveguide 151. That is, the edge coupler 152 may have a different horizontal width from other areas of the waveguide 151 for accuracy in transmitting/receiving optical signals. For example, the horizontal width of the edge coupler 152 may become narrower as it approaches the glass connector 153.

According to an embodiment, an optical path 153_w, which is connected to the edge coupler 152 and through which an optical signal may move, may be formed inside the glass connector 153.

In some embodiments, the edge coupler 152 may have a constant length, that is, a constant thickness, in the vertical direction (the Z direction). For example, the edge coupler 152 may have a constant thickness in all areas, unlike a grating coupler. That is, the thickness of the edge coupler 152 may be the same as the thicknesses of other areas of the waveguide 151.

According to an embodiment, a dummy chip 140 may be disposed on the waveguide 151, and the second insulating layer 141 may be disposed between the dummy chip 140 and the waveguide 151. The dummy chip 140 may be arranged to overlap the photodiode 162 in the vertical direction (the Z direction). The dummy chip 140 may be configured to dissipate heat emitted from the photodiode 162.

According to an embodiment, the distance from the sidewall of the optical integrated circuit chip 111 to the outermost portion of the glass connector 153 may be in a range of about 0.01 mm to about 100 mm. That is, the glass connector 153 may include a protrusion protruding outward from the sidewall of the optical integrated circuit chip 111, and a distance d3 of the protrusion in the first horizontal direction (the X direction) may be in a range of about 0.01 mm to about 100 mm.

In addition, according to an embodiment, the sidewall of the interposer substrate 401 may be located on the same plane as the sidewall of the photonics chip structure 100.

The semiconductor package 10 according to the technical idea of the inventive concept may provide the photonics chip structure 100 in which the optical integrated circuit chip 111 and the electronic integrated circuit chip 121 are vertically stacked. By vertically stacking the optical integrated circuit chip 111 and the electronic integrated circuit chip 121, an electrical signal distance between the photonics chip structure 100 and another chip (for example, a logic chip or a memory chip) may be shortened. According to an embodiment, the vertical height d4 of the photonics chip structure 100 may be in a range of about 0.05 mm to about 2 mm.

In addition, the photonics chip structure 100 of the semiconductor package 10 according to the technical idea of the inventive concept may include the glass connector 153 attached on the optical integrated circuit chip 111 and the dummy chip 140 facing the glass connector 153. The glass connector 153 may be fastened to the groove GR of the optical integrated circuit chip 111, and the dummy chip 140 may provide a space for the glass connector 153 to be more stably seated.

According to one embodiment, an optical path PI, which is a path through which light passes, may be formed inside the edge coupler 152. For example, the optical path PI may be a waveguide, but is not necessarily limited thereto. For example, the optical path PI may be patterned inside the edge coupler 152 to provide a path for light to advance through reflection.

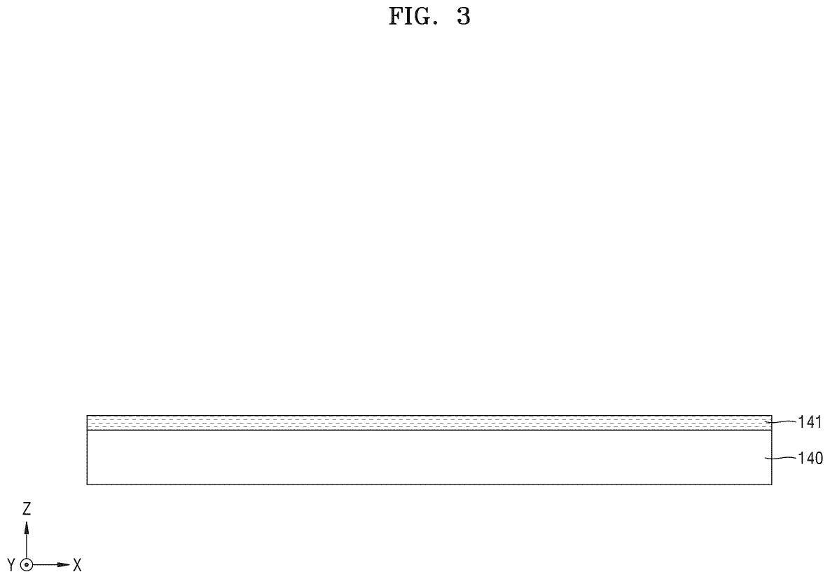

FIGS. 3 to 15 are cross-sectional views sequentially illustrating a process of manufacturing a semiconductor package according to an example embodiment.

Referring to FIG. 3, first, a dummy chip 140 and a second insulating layer 141 may be provided. In this case, the dummy chip 140 and the second insulating layer 141 may each have an upper surface extending in a horizontal direction (an X direction and/or a Y direction).

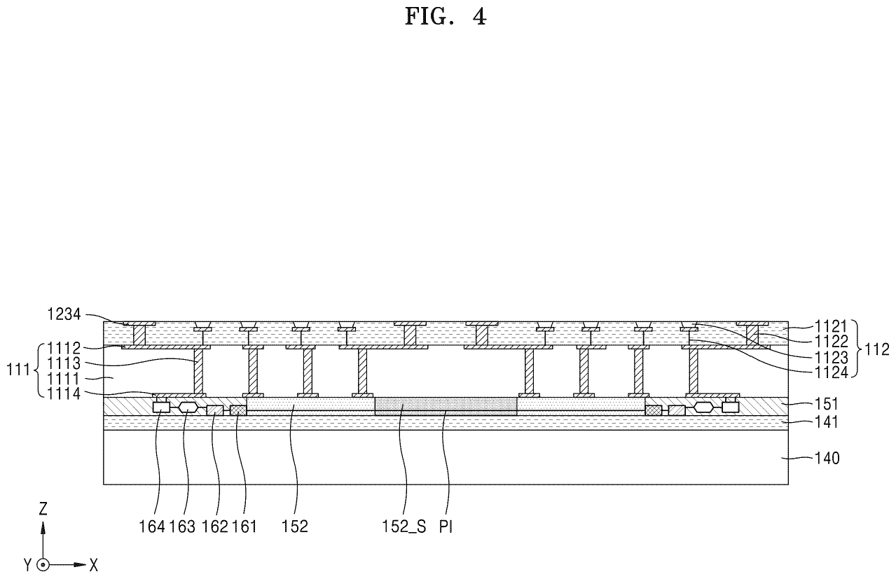

Referring to FIG. 4, an optical integrated circuit portion 110 may be formed on the second insulating layer 141. In this case, a waveguide 151 may be formed to have a constant thickness on the upper surface of the second insulating layer 141. A waveguide sacrificial portion 152_S may be disposed at the center of the waveguide 151. The waveguide sacrificial portion 152_S is a partial area of the waveguide 151, and a path through which an optical signal passes is formed in the waveguide sacrificial portion 152_S. In this case, the path formed in the waveguide sacrificial portion 152_S is an area connected to an optical signal path of the waveguide 151. The lower surface of the waveguide sacrificial portion 152_S may be in contact with the second insulating layer 141, and the side and upper surfaces of the waveguide sacrificial portion 152_S may be in contact with the waveguide 151. That is, the waveguide sacrificial portion 152_S is an area that will be removed later to form a groove in the waveguide 151.

A PIC wiring portion 112 may be formed on the top of an optical integrated circuit chip 111. Parts of a PIC conductive pad 1123 and a PIC conductive pattern 1122, which function as pads, may be exposed on the upper surface of the PIC wiring portion 112.

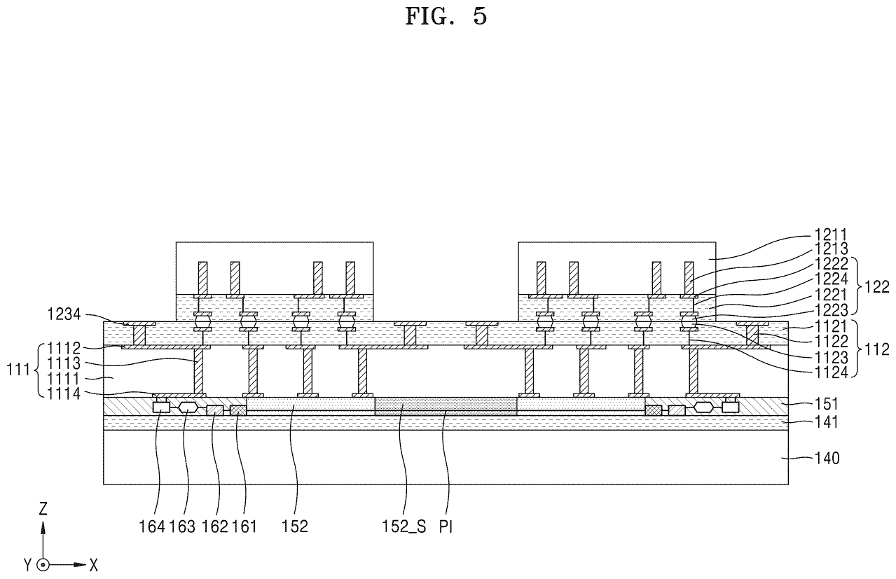

Referring to FIG. 5, a second substrate 1211 with an EIC wiring portion 122 formed at the bottom thereof may be attached to the PIC wiring portion 112. In this case, an EIC insulating layer 1221 and a PIC insulating layer 1121 may be bonded to each other, and a PIC lower pad 1112 may be bonded to an EIC lower pad 1212. Bonding between the EIC insulating layer 1221 and the PIC insulating layer 1121 and bonding between the PIC lower pad 1112 and the EIC lower pad 1212 may be hybrid bonding.

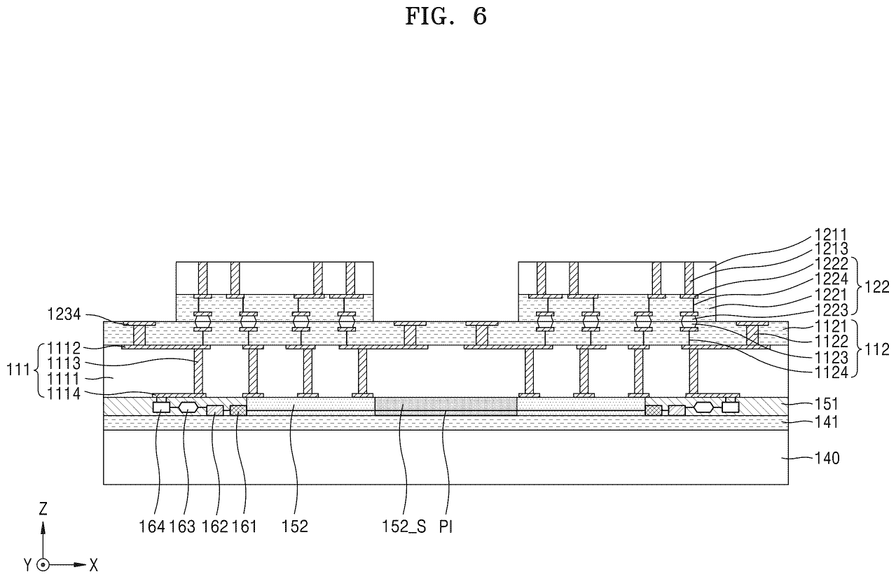

Referring to FIG. 6, an upper portion of the second substrate 1211 may be ground. By grinding the upper portion of the second substrate 1211, the upper surface of an EIC through-electrode 1213 may be exposed to the upper surface of the second substrate 1211. The grinding process may be performed as a chemical mechanical polishing (CMP) process, but is not necessarily limited thereto.

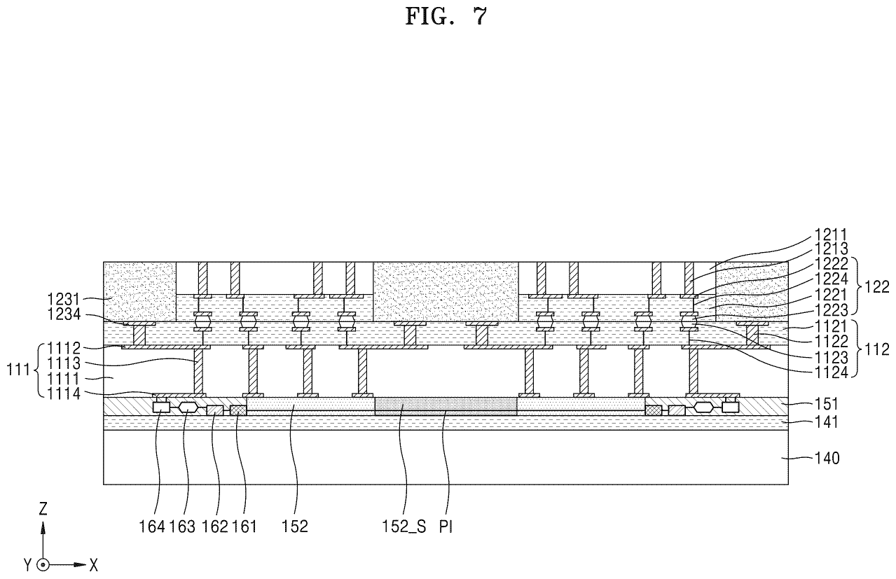

Referring to FIG. 7, an outer insulating layer 1231 may be formed on the PIC wiring portion 112. The outer insulating layer 1231 may be formed along the PIC insulating layer 1121 of the PIC wiring portion 112 and may be formed to surround the optical integrated circuit portion 110. Specifically, the outer insulating layer 1231 may be formed to contact the side surface of the EIC insulating layer 1221 and the side surface of the second substrate 1211. The upper surface of the outer insulating layer 1231 may be flush with the upper surface (or an active surface) of the second substrate 1211 to which an EIC through-electrode 1213 is exposed. For example, the upper surface of the outer insulating layer 1231 may be coplanar with the upper surface (or an active surface) of the second substrate 1211.

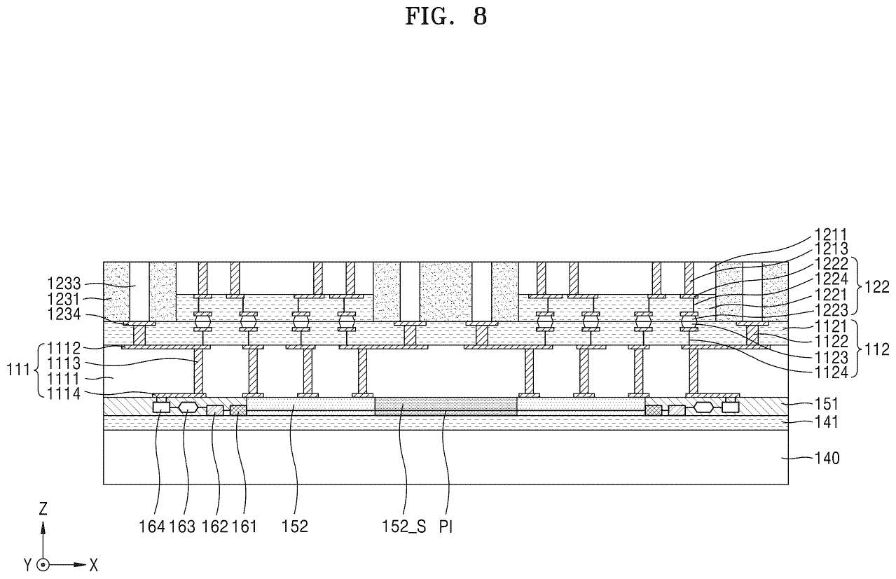

Referring to FIG. 8, a vertical connection conductor 1233, which passes through the outer insulating layer 1231 in a vertical direction (a Z direction), may be formed. The vertical connection conductor 1233 may extend from the upper surface of the outer insulating layer 1231 to the lower surface thereof, and a lower end of the vertical connection conductor 1233 may be connected to the EIC conductive pattern 131 of the EIC wiring portion 122. The vertical connection conductor 1233 may be thicker than the EIC conductive pattern 131 or the EIC through-electrode 1213. Therefore, even when the electronic integrated circuit chip 121, which has a smaller area than the optical integrated circuit chip 111, is later placed below the optical integrated circuit chip 111, the structural stability of the photonics chip structure 100 may be maintained. The vertical height of the vertical connection conductor 1233 may be greater than the vertical height of the electronic integrated circuit chip 121.

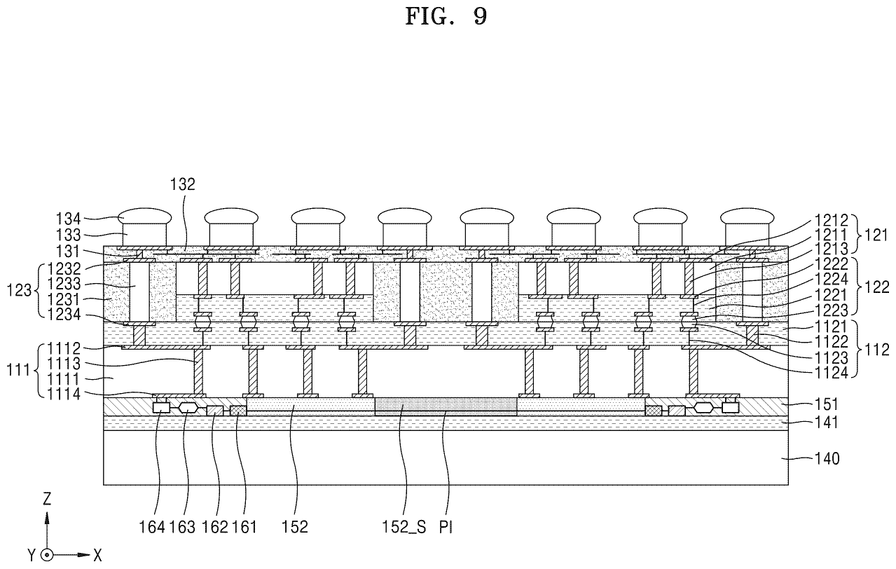

Referring to FIG. 9, a photonics wiring structure 130 may be formed on the lower surfaces of the outer insulating layer 1231 and the optical integrated circuit chip 111. In this case, before the photonics wiring structure 130 is formed, a second intermediate conductive pattern layer 1234 connected to the upper surface of the vertical connection conductor 1233 formed in the outer insulating layer 1231 may be formed, and a first intermediate conductive pattern layer 1232 connected to the lower surface of the vertical connection conductor 1233 formed in the outer insulating layer 1231 may be formed. The second intermediate conductive pattern layer 1234 may be formed along the upper surface of the vertical connection conductor 1233, and the first intermediate conductive pattern layer 1232 may be formed along the lower surface of the vertical connection conductor 1233.

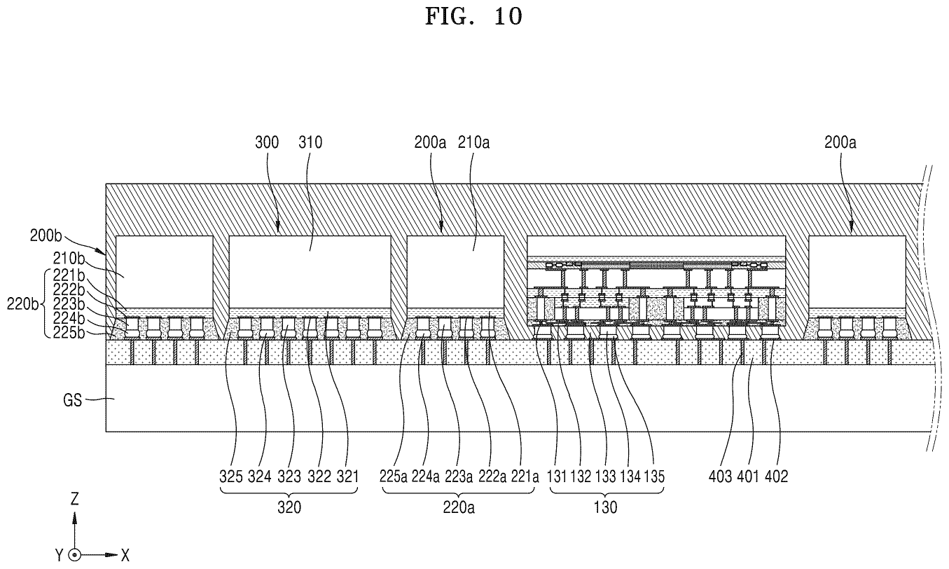

Referring to FIGS. 9 and 10, a first memory chip structure 200a and a second memory chip structure 200b are formed on both sides of the photonics chip structure 100, and a logic chip structure 300 disposed between the first memory chip structure 200a and the second memory chip structure 200b is formed. Thereafter, a glass substrate GS with an interposer 400 attached to the bottoms of the photonics chip structure 100, the first memory chip structure 200a, the second memory chip structure 200b, and the logic chip structure 300 is disposed. The photonics chip structure 100, the first memory chip structure 200a, the second memory chip structure 200b, and the logic chip structure 300 may be attached to the upper surface of the interposer 400.

After the photonics chip structure 100, the first memory chip structure 200a, the second memory chip structure 200b, and the logic chip structure 300 are attached to the upper surface of the interposer 400, a molding layer 570 that seals the photonics chip structure 100, the first memory chip structure 200a, the second memory chip structure 200b, and the logic chip structure 300 may be formed. In this case, the molding layer 570 may be formed by injecting a molding material using a transfer molding method or a compression molding method.

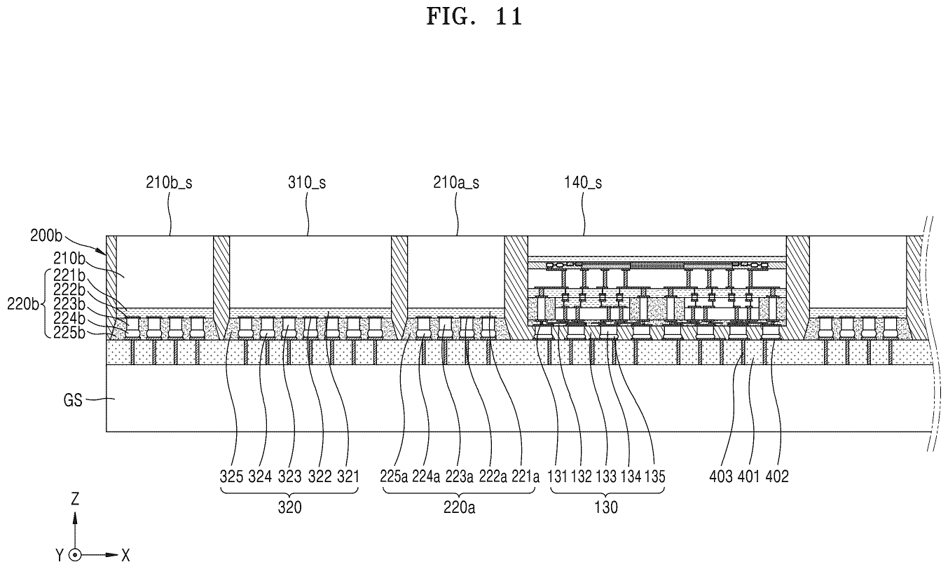

Referring to FIG. 11, portions of the tops of a first memory chip 210a, a second memory chip 210b, a logic chip 310, and a dummy chip 140 may be ground along with a portion of the top of the molding layer 570. Through the grinding, an upper surface 570_s of the molding layer 570, an upper surface 210a_s of the first memory chip 210a, an upper surface 210b_s of the second memory chip 210b, an upper surface 310_s of the logic chip 310, and an upper surface 140_s of the dummy chip 140 may all be located on the same plane.

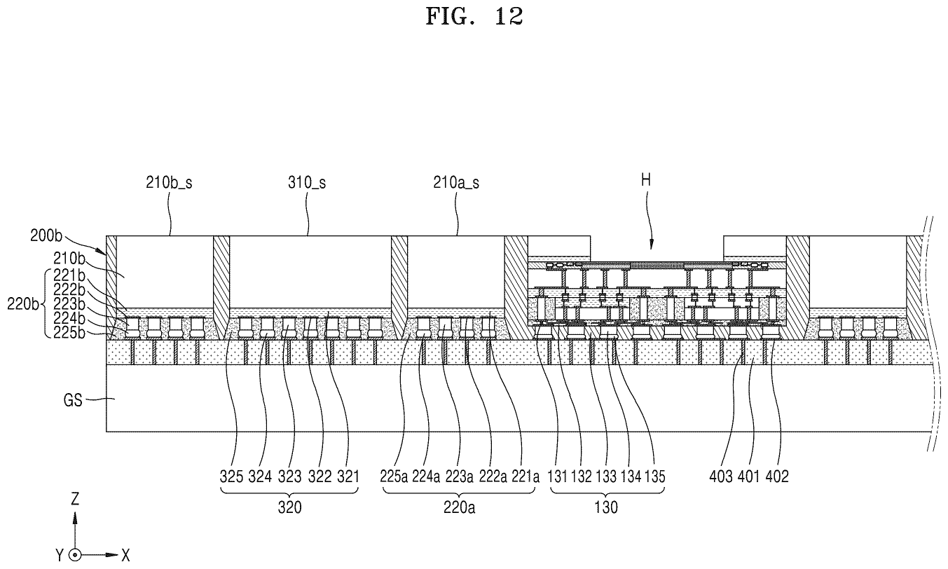

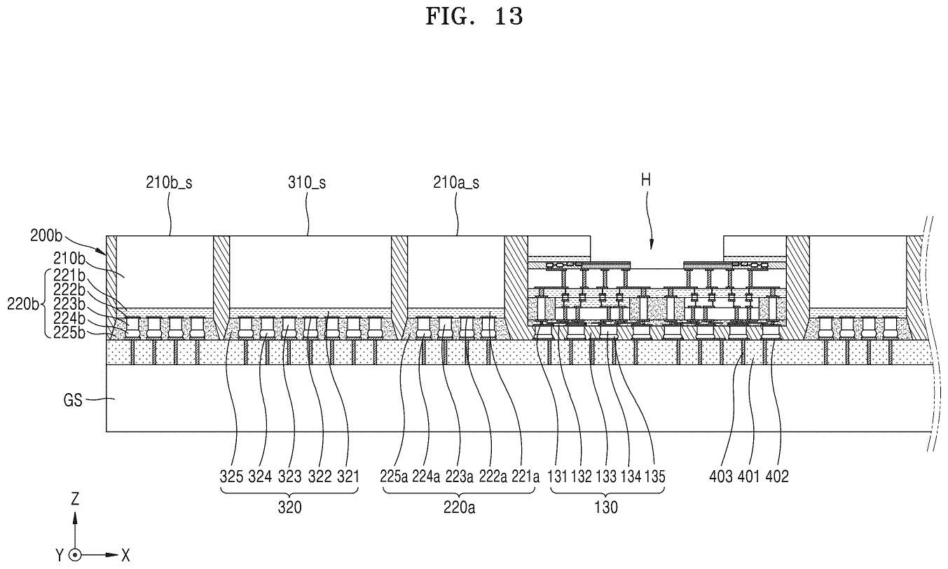

Referring to FIGS. 12 and 13, a central portion of the dummy chip 140 and a central portion of the second insulating layer 141 may be etched to form a hole H. The entire upper surface of the waveguide sacrificial portion 152_S and a portion of the upper surface of the waveguide 151 may be exposed through the hole H. The sidewall of the dummy chip 140 and the sidewall of the second insulating layer 141 may be exposed to the sidewall of the hole H.

After the central portion of the dummy chip 140 and the central portion of the second insulating layer 141 are etched, the waveguide sacrificial portion 152_S may be removed. When the waveguide sacrificial portion 152_S is removed, a groove may be formed in the center of the waveguide 151.

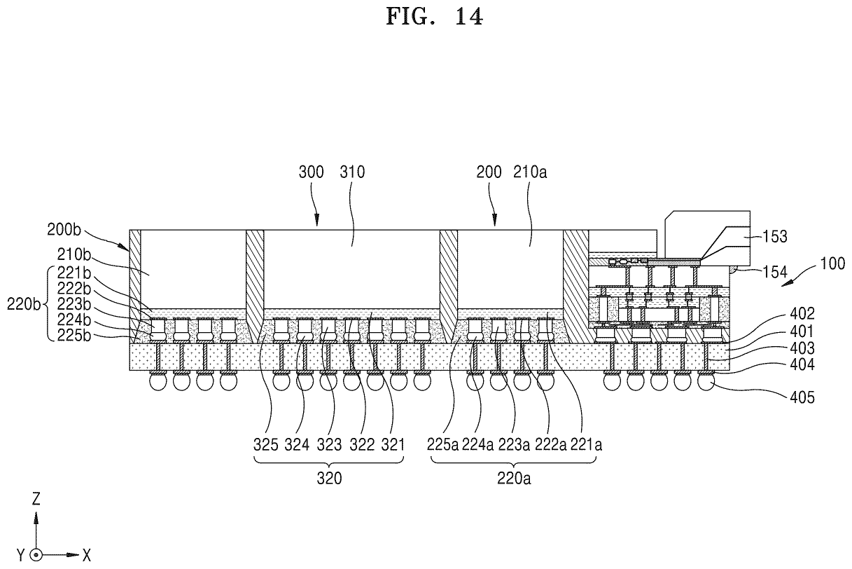

Thereafter, referring to FIGS. 13 and 14, half of the interposer 400 may be cut using the center of the photonics chip structure 100 and the center of the interposer 400 as a cutting line. Thereafter, an interposer lower pad 404 may be formed on the lower surface of an interposer substrate 401. Thereafter, an interposer connection terminal 405 is formed on the interposer lower pad 404.

After the interposer connection terminal 405 is formed, an adhesive member 550 is attached to a groove GR of the optical integrated circuit portion 110, and a glass connector 153 is bonded to the adhesive member 550.

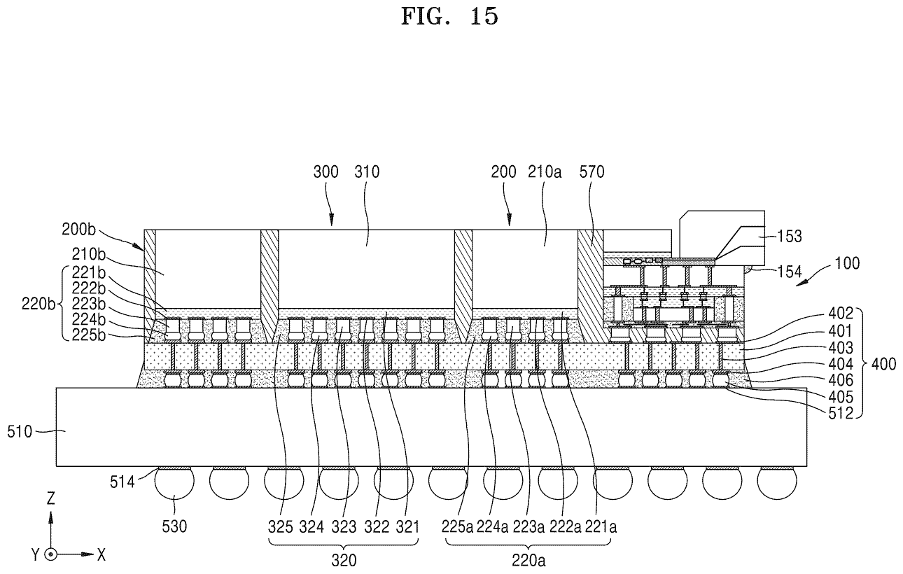

Next, referring to FIG. 15, the interposer connection terminal 405 is attached on a package substrate 510 to which a package lower pad 514 and a package connection terminal 530 are attached. Thereafter, an interposer terminal protection layer 406 surrounding the interposer connection terminal 405 and the interposer lower pad 404 is formed.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate;
an interposer substrate disposed on the package substrate; and
a photonics chip structure mounted on the interposer substrate,
wherein the photonics chip structure comprises:
an electronic integrated circuit portion including an electronic integrated circuit chip mounted on the interposer substrate;
an optical integrated circuit portion including an optical integrated circuit chip having a groove at a corner of an upper portion thereof and mounted on the electronic integrated circuit chip, an edge coupler extending toward the groove, and a waveguide connected to the edge coupler; and
a glass connector mounted in the groove of the optical integrated circuit portion and facing the edge coupler.

2. The semiconductor package of claim 1, further comprising a dummy chip disposed on the optical integrated circuit portion to face the glass connector.

3. The semiconductor package of claim 2,
wherein the optical integrated circuit portion further includes a photodiode connected to the waveguide and configured to receive an optical signal from the edge coupler, and
wherein the dummy chip overlaps the photodiode in a vertical direction.

4. The semiconductor package of claim 2, further comprising:
a heat dissipation member covering the dummy chip,
wherein the heat dissipation member is spaced apart from the glass connector in a horizontal direction and does not overlap the glass connector in a vertical direction.

5. The semiconductor package of claim 4, wherein an area of an upper surface of the heat dissipation member is less than an area of an upper surface of the interposer substrate.

6. The semiconductor package of claim 1, wherein the glass connector includes a protrusion protruding outward from a sidewall of the optical integrated circuit chip.

7. The semiconductor package of claim 6, wherein a distance from the sidewall of the optical integrated circuit chip to an outermost portion of the protrusion of the glass connector is in a range of about 0.01 mm to about 100 mm.

8. The semiconductor package of claim 1, where an area of an upper surface of the optical integrated circuit chip is greater than an area of an upper surface of the electronic integrated circuit chip.

9. The semiconductor package of claim 1,
wherein the electronic integrated circuit portion further includes a vertical connection conductor surrounding the electronic integrated circuit chip, and
wherein a vertical height of the vertical connection conductor is greater than a vertical height of the electronic integrated circuit chip.

10. The semiconductor package of claim 1,
wherein the optical integrated circuit portion further includes a photonics integrated circuit (PIC) insulating layer disposed below the optical integrated circuit chip, and a PIC conductive pad buried in the PIC insulating layer,
wherein the electronic integrated circuit portion further includes an electronics integrated circuit (EIC) insulating layer disposed below the PIC insulating layer, and an EIC conductive pad buried in the EIC insulating layer, and
wherein the PIC insulating layer and the PIC conductive pad are hybrid-bonded with the EIC insulating layer and the EIC conductive pad, respectively.

11. The semiconductor package of claim 1, wherein a vertical height of the photonics chip structure is in a range of about 0.05 mm to about 2 mm.

12. A semiconductor package comprising:
a package substrate;
an interposer substrate disposed on the package substrate;
a photonics chip structure mounted on the interposer substrate;
a logic chip structure disposed on the interposer substrate and spaced apart from the photonics chip structure in a horizontal direction; and
a memory chip structure disposed to face a side surface of the logic chip structure,
wherein the photonics chip structure comprises:
an electronic integrated circuit portion including an electronic integrated circuit chip mounted on the interposer substrate;
an optical integrated circuit portion including an optical integrated circuit chip having a groove at a corner of an upper portion thereof and mounted on the electronic integrated circuit chip, an edge coupler disposed to correspond to the groove, and a waveguide connected to the edge coupler;
a glass connector mounted in the groove of the optical integrated circuit portion and facing the edge coupler; and
a dummy chip disposed on the optical integrated circuit portion to face the glass connector.

13. The semiconductor package of claim 12, wherein a sidewall of the interposer substrate is located on a same plane as a sidewall of the photonics chip structure.

14. The semiconductor package of claim 12, further comprising:
a heat dissipation member that completely overlaps upper surfaces of the logic chip structure and the memory chip structure and partially overlaps an upper surface of the photonics chip structure,
wherein the heat dissipation member is spaced apart from the glass connector in the horizontal direction and does not overlap the glass connector in a vertical direction.

15. The semiconductor package of claim 14,
wherein an area of a portion of a total area of the upper surface of the photonics chip structure is in a range of about 2% to about 80% of the total area, and
wherein the portion of the total area of the upper surface of the photonics chip structure does not overlap the heat dissipation member.

16. The semiconductor package of claim 12,
wherein the optical integrated circuit portion further includes a photonics integrated circuit (PIC) insulating layer disposed below the optical integrated circuit chip, and a PIC conductive pad buried in the PIC insulating layer,
wherein the electronic integrated circuit portion further includes an electronics integrated circuit (EIC) insulating layer disposed below the PIC insulating layer, and an EIC conductive pad buried in the EIC insulating layer, and
wherein the PIC insulating layer and the PIC conductive pad are hybrid-bonded with the EIC insulating layer and the EIC conductive pad, respectively.

17. The semiconductor package of claim 12, wherein an upper surface of the dummy chip is located on a same plane as an uppermost surface of the logic chip structure and an uppermost surface of the memory chip structure.

18. The semiconductor package of claim 12, further comprising:
a conductive post surrounding the electronic integrated circuit chip,
wherein a vertical height of the conductive post is greater than a vertical height of the electronic integrated circuit chip.

19. A semiconductor package comprising:
a package substrate;
an interposer substrate disposed on the package substrate;
a photonics chip structure mounted on the interposer substrate;
a logic chip structure disposed on the interposer substrate and spaced apart from the photonics chip structure in a horizontal direction;
a first memory chip structure disposed to face a first side surface of the logic chip structure; and
a second memory chip structure facing a second side surface opposite to the first side surface and disposed between the photonics chip structure and the logic chip structure,
wherein the photonics chip structure comprises:
a photonics substrate;
an electronic integrated circuit portion including an electronic integrated circuit chip mounted on the photonics substrate;
an optical integrated circuit portion having a groove at a corner of an upper portion thereof and mounted on the electronic integrated circuit chip, the optical integrated circuit portion including an edge coupler disposed to correspond to the groove and a first waveguide connected to the edge coupler;
a glass connector mounted in the groove of the optical integrated circuit portion and facing the edge coupler; and
a dummy chip disposed next to the glass connector on the optical integrated circuit portion, the dummy chip having an upper surface on a same plane as a vertical level of an uppermost surface of the logic chip structure, a vertical level of an uppermost surface of the first memory chip structure, and a vertical level of an uppermost surface of the second memory chip structure.

20. The semiconductor package of claim 19, wherein the glass connector includes a plurality of second waveguides configured to transmit an optical signal to the edge coupler.
